(19) United States
(12) Patent Application Publication
(10) Pub. No.: US 2026/0092997 A1
(43) Pub. Date: Apr. 2, 2026

(54) Acquisition of Scan Data with a Magnetic Resonance System Using Ultra-Short Echo Times

(71) Applicant: Siemens Healthineers AG, Forchheim (DE)

(72) Inventor: David Grodzki, Erlangen (DE)

(73) Assignee: Siemens Healthineers AG, Forchheim (DE)

(21) Appl. No.: 19/338,280

(22) Filed: Sep. 24, 2025

(30) Foreign Application Priority Data
Sep. 30, 2024 (DE) 10 2024 209 504.4

(51) Int. Cl. G01R 33/48; G01R 33/38; G01R 33/54

(52) U.S. Cl. CPC G01R 33/4816; G01R 33/3804; G01R 33/4822; G01R 33/543

(57) ABSTRACT

The disclosure is directed to a method for the acquisition of scan data of an examination object by a magnetic resonance system with a sequence using ultra-short echo times. The method may include loading the half-spokes to be sampled in k-space for the desired acquisitions in k-space with the associated gradients to be switched on three axes of a gradient unit of the magnetic resonance system for spatial encoding, determining a sequence of acquisitions of scan data to be acquired one after the other along each half-spoke with a distribution of the gradients to be switched on the axes that is optimized with respect to the load on the axes, and performing the acquisitions of the scan data along the half-spokes to be sampled according to the sequence determined.

### CROSS REFERENCE TO RELATED APPLICATIONS

This patent application claims priority to German Patent Application No. 102024209504.4, filed Sep. 30, 2024, which is incorporated herein by reference in its entirety.

### BACKGROUND

The disclosure relates to improved acquisition of scan data with a magnetic resonance system using ultra-short echo times, in particular to improvements in the acquisition of scan data by means of a sequence that samples k-space along half-spokes, such as for example a PETRA sequence, a zTE sequence, a WASPI sequence or a UTE sequence.

Magnetic resonance technology (hereinafter, the abbreviation MR stands for magnetic resonance) is a known technology for generating images of the interior of an examination object. In simplified terms, this is done by placing the examination object in a magnetic resonance device in a comparatively strong static homogeneous main magnetic field, also called the B0 field, at field strengths of 0.2 Tesla to 7 Tesla and higher, so that nuclear spins of the examination object are oriented along the main magnetic field. Radio-frequency excitation pulses (RF pulses) are radiated into the examination object in order to induce nuclear spin resonances that can be measured as signals; the induced nuclear spin resonances are measured as so-called k-space data using coils designed for reception and used as the basis for reconstructing MR images or ascertaining spectroscopic data. The alternating magnetic field generated by the excitation pulses radiated by at least one transmitting coil is also referred to as the B1 field. For spatial encoding of the scan data, rapidly switched magnetic gradient fields, or simply gradients, are overlaid on the main magnetic field. A scheme that describes a temporal sequence of RF pulses to be radiated and gradients to be switched is referred to as a pulse sequence (scheme), or simply sequence. The scan data acquired is digitized and stored as complex numerical values in a k-space matrix. An associated MR image can be reconstructed from the k-space matrix loaded by values, for example by means of a multi-dimensional Fourier transform.

It is not possible to use MR sequences to depict substances or tissues with a T2* time, the effective decay of the transverse magnetization of this substance or tissue, which is significantly shorter than the shortest possible echo times within these sequences, since a corresponding signal from these substances or tissues has already decayed at the time of acquisition.

Therefore, it is not possible to use conventional sequences, such as, for example, a (T)SE sequence (“(turbo) spin echo”) or a GRE sequence (“gradient echo”) to acquire substances or tissues, such as, for example, bones, tendons, ligaments, teeth or even ice that have T2* times of significantly below 500 microseconds (μs).

However, MR methods are already known that allow very short echo times TE (for example TE<500 μs or, with appropriate hardware, even TE<50 μs), which are within the range of the corresponding decay time. These make it possible, for example, to depict bones, tendons, ligaments, teeth or ice in an MR image, even though the T2* time of such substances or tissues is in a range of 30-80 μs.

These MR methods include, for example, the UTE sequence (“ultrashort echo time”) as described inter alia in the article by Sonia Nielles-Vallespin “3D radial projection technique with ultrashort echo times for sodium MRI: Clinical applications in human brain and skeletal muscle”, Magn. Res. Med. 2007; 57; pp. 74-81. With this sequence type, after a waiting time following non-slice selective or slice-selective excitation, data acquisition begins simultaneously with the ramp-up of the gradients for spatial encoding. The k-space trajectory sampled in this way runs radially from the k-space center outward and hence along a half-spoke. Therefore, before the image data can be reconstructed from the raw data acquired in k-space using a Fourier transform, this raw data must first be converted to a Cartesian k-space grid, for example by regridding.

Further MR methods that allow particularly short echo times are zTE (“zero echo time”) and PETRA (“pointwise encoding time reduction with radial acquisition”) or WASPI (“water and fat-suppressed proton projection MRI”) sequences and are, for example, described in the article by Weiger et al., “MRI with Zero Echo Time: Hard versus Sweep Pulse Excitation” Magnetic Resonance in Medicine 66: pp. 379-389, 2011, in U.S. Pat. No. 8,878,533B2 (PETRA) and in the article by Wu et al., “Density of Organic Matrix of Native Mineralized Bone Measured by Water- and Fat-Suppressed Proton Projection MRI”, Magn. Reson. Med. 50: pp. 59-68, 2003. In both methods, scan data is acquired in k-space along radial half-spokes whose gradients that are switched for spatial encoding are already fully ramped up at the time of spin excitation in an examination object, which saves valuable encoding time. However, this also creates a region in the k-space center that cannot be sampled by these radial half-spokes. zTE and PETRA methods are more robust than UTE methods since eddy currents or unwanted small time shifts of switched gradients or radiated RF pulses have no influence, or at most a negligible influence, on the scans.

### BRIEF DESCRIPTION OF THE DRAWINGS/FIGURES

The accompanying drawings, which are incorporated herein and form a part of the specification, illustrate the embodiments of the present disclosure and, together with the description, further serve to explain the principles of the embodiments and to enable a person skilled in the pertinent art to make and use the embodiments.

FIG. 1 is a schematic depiction of a portion of an example pulse sequence scheme for capturing scan data.

FIG. 2 is a schematic depiction of an example k-space sampling scheme.

FIG. 3 is a flowchart of a method for the acquisition of scan data from an examination object using a magnetic resonance system with a sequence using ultra-short echo times, according to an exemplary embodiment of the present disclosure.

FIG. 4 shows a magnetic resonance system according to an exemplary embodiment of the present disclosure.

The exemplary embodiments of the present disclosure will be described with reference to the accompanying drawings. Elements, features and components that are identical, functionally identical and have the same effect are—insofar as is not stated otherwise—respectively provided with the same reference character.

### DETAILED DESCRIPTION

In the following description, numerous specific details are set forth in order to provide a thorough understanding of the embodiments of the present disclosure. However, it will be apparent to those skilled in the art that the embodiments, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring embodiments of the disclosure. The connections shown in the figures between functional units or other elements can also be implemented as indirect connections, wherein a connection can be wireless or wired. Functional units can be implemented as hardware, software or a combination of hardware and software.

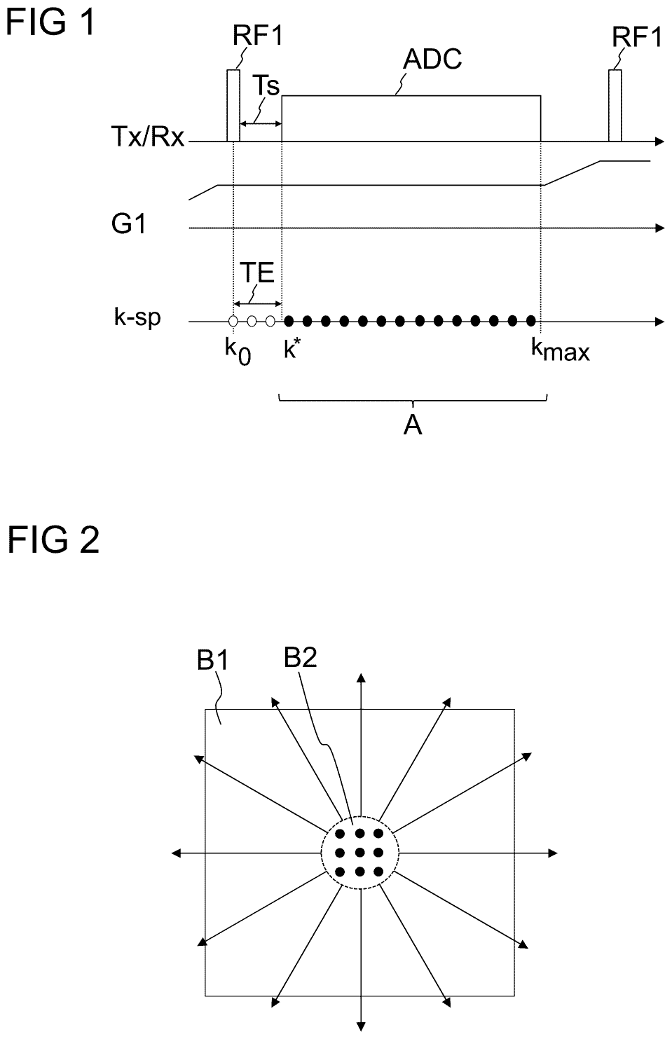

FIG. 1 shows an example of part of a pulse sequence for such acquisition A of scan data along radial half-spokes, as used in zTE methods and PETRA methods. The upper row “Tx/Rx” depicts the radiated RF excitation pulses RF1 and the readout time windows ADC during which the acquisition A of the scan data takes place. The middle row “G1” depicts the gradients switched in an encoding direction which in each case have reached their desired strength at the time of the radiation of an RF excitation pulse RF1 for the subsequent acquisition A of scan data. The lower row “k-sp” depicts the associated k-space points sampled along the k-space trajectory specified by the applied gradient field for the acquisition A of the scan data. Here, scanned k-space points are shown as black dots and k-space points lying before the start of the readout time window, and therefore not read out, are shown as “empty” dots. The fact that k-space points are not read out is due to the fact that, as described, a constant gradient field is already applied before the radiation of the RF excitation pulse RF. This would mean that the central k-space point (ko) would have to be scanned at the same time as the radiation of the RF excitation pulse RF1, which is not technically possible. Only after a minimum switching time Ts required after the end of the RF excitation pulse RF1, which depends on the hardware of the magnetic resonance system used, can the acquisition A of the scan data begin in the readout time window ADC, which still results in the shortest possible echo time TE. The first k-space point k* read out in the readout time window ADC has the minimum distance from the k-space center ko among the k-space points read out. The last k-space point kₘₐₓ read out in the readout time window ADC has the maximum distance from the k-space center ko among the k-space points read out. The duration of the readout time window ADC (acquisition time) is determined by the strength of the applied gradient field G1 and the required resolution or the desired field of view (FOV) or the matrix of the image to be created from the scan data.

FIG. 2 shows an associated sampling scheme of the k-space. In this example, a radial half-spoke in k-space corresponds to a k-space trajectory along which scan data is acquired in a readout time window ADC. In the region B1, scan data is acquired along radial half-spokes in different encoding directions until, for example, a desired sampling density in k-space is reached. The radius of the central region B2, in which no scan data is acquired along the described radial half-spokes because the amount of a distance of a k-space point k is smaller than k*, depends on the k-space moment accumulated after excitation until the acquisition A of the scan data and thus on the echo time TE in which the gradient is switched with constant strength, and the strength of the switched gradient field G. FIG. 2 only shows one plane in k-space. The sampling scheme is often performed in all three dimensions, wherein the half-spokes sampled in k-space in the acquisitions A of the scan data extend from a spherical surface of a sphere with the radius k* to a spherical surface of a sphere with the radius kₘₐₓ.

In zTE methods, MR data from this non-radially sampled region B2 can be algebraically constructed from the scan data of the radial half-spokes. In WASPI methods, a small number of further scans are performed along second radial k-space trajectories, wherein the strength of the gradients is reduced in order still to be able to acquire scan data closer to the k-space center.

In PETRA methods, scan data from the non-radially sampled region B2 can be acquired using a MR single-point acquisition method, for example RASP (“rapid single point”) such as, for example, described in the article by Heid et al., “Rapid Single Point (RASP) imaging”, Proc. Intl. Soc. Mag. Reson. Med., p. 684, 1995, or a “single point SPRITE” method such as, for example, described in the article by Balcom et al., “Single-Point Ramped Imaging with T1 Enhancement (SPRITE)”, J. Magn. Reson. A 123(1): pp. 131-134, 1996, in particular on a Cartesian grid. This is roughly schematically depicted in FIG. 2 by filled dots in the region B2, which represent individual acquired k-space points.

In addition to an extremely short echo time TE, rapid readout of the acquired scan data, i.e. a short readout time window, is important in order to be able to achieve the highest possible resolution and thus generate the sharpest possible image data. Unlike an extremely short echo time TE, which ensures that as much signal as possible is present in the k-space center, a short readout time window leads to more signal and thus more information in an outer region of k-space. More signal in an outer region of the sampled k-space leads to greater signal strength of the rapidly decaying signals. Greater signal strength allows for the generation of sharper images. It has been calculated that optimum resolution can be achieved if the readout time window is of the same order of magnitude as the T2 time of the tissue of the examination object to be mapped.

In order to be able to apply a short readout time window, scans must be performed with very high readout bandwidths. Using high readout bandwidths reduces the overall signal-to-noise ratio achieved. However, this can, for example, be compensated by averaging methods in which scan data is acquired multiple times and an average is calculated. Since the shorter readout time window allows for shorter repetition times TR, the overall scan time is not necessarily longer. Additionally or alternatively, it is possible to use methods such as denoising or other deep-learning-based methods to compensate the reduced overall SNR.

Furthermore, depending on the desired resolution, a high readout bandwidth also requires high gradient strengths during the readout time window. Theoretically, gradient strengths of >100 mT/m would be required for the best possible resolution of rapidly decaying signals. However, such high gradient strengths cannot be achieved with all common magnetic resonance systems.

To ensure that scans using ultra-short echo times do not exceed the hardware-related limitations of a magnetic resonance system, in particular its gradient power amplifier (GPA) and other parts of its gradient unit and its cooling system, the available gradients Gnom, which can be switched to their maximum within the scope of a sequence for ultra-short echo times, are therefore usually limited on the individual axes (x,y,z) of the gradient unit to values well below the maximum amplitude GMax possible on an axis, for example to 60-70% of GMax.

However, sequences using ultra-short echo times are embodied such that gradients are to be switched continuously and only the distribution of the gradients to be switched on the axes changes from repetition to repetition, but not the total power G\hat{ }2=Gx\hat{ }2+Gy\hat{ }2+Gz\hat{ }2. Therefore, playing these sequences is very challenging for the GPA and the entire gradient unit.

An object of the present disclosure is to enable a scan with a sequence using an ultra-short echo time and the largest possible bandwidth. The object is achieved by one or more exemplary embodiments and/or aspects of the present disclosure.

A method according to the disclosure for the acquisition of scan data from an examination object, by a magnetic resonance system with a sequence using ultra-short echo times, may comprise:
loading the half-spokes to be sampled in k-space for the desired acquisitions in k-space with the associated gradients to be switched on three axes of a gradient unit of the magnetic resonance system for spatial encoding,
determining a sequence of acquisitions of scan data to be acquired one after the other along each half-spoke with a distribution of the gradients to be switched on the axes that is optimized with respect to the load on the axes, and
performing the acquisitions of the scan data along the half-spokes to be sampled according to the determined sequence.

Optimized determination according to the disclosure of a sequence in which half-spokes are to be sampled using ultra-short echo times one after the other during a scan of an examination object enables higher gradient strengths (amplitudes) for the gradients to be switched for spatial encoding than has been the case to date. In particular, gradient strengths of more than 70%, for example 80%, 90%, or even more, of a maximum possible gradient strength Gmax on an axis of the gradient unit can be permitted for the acquisition of half-spokes to be sampled. Hence, the method according to the disclosure enables shorter readout time windows in sequences using ultra-short echo times. This improves image quality and image sharpness and hence the resolution of substances in the examination object with very rapidly decaying signals.

A magnetic resonance system according to the disclosure may comprise a magnet unit, a gradient unit, a radio-frequency unit, and a control facility (controller) embodied to perform a method according to the disclosure with an optimization unit.

A computer program according to the disclosure implements a method according to the disclosure on a controller when it is executed on the controller. For example, the computer program may comprise instructions which, when the program is executed by a controller, for example a controller of a magnetic resonance system, cause this controller to execute a method according to the disclosure. The controller can be embodied in the form of a computer or other processing circuitry.

The computer program can also be present in the form of a computer program product, which can be loaded directly into a memory of a controller, with program code means for executing a method according to the disclosure when the computer program product is executed in a computing unit of a computing system of the controller.

A computer-readable storage medium according to the disclosure may comprise instructions which, when executed by a controller, for example a controller of a magnetic resonance system, cause the controller to execute a method according to the disclosure.

The computer-readable storage medium can be embodied as an electronically readable data carrier which may comprise electronically readable control information stored thereon and which may comprise at least one computer program according to the disclosure and is embodied such that, when the data carrier is used in a controller of a magnetic resonance system, it performs a method according to the disclosure.

The advantages and embodiments specified in relation to the method also apply analogously to the magnetic resonance system, the computer program product and the electronically readable data carrier.

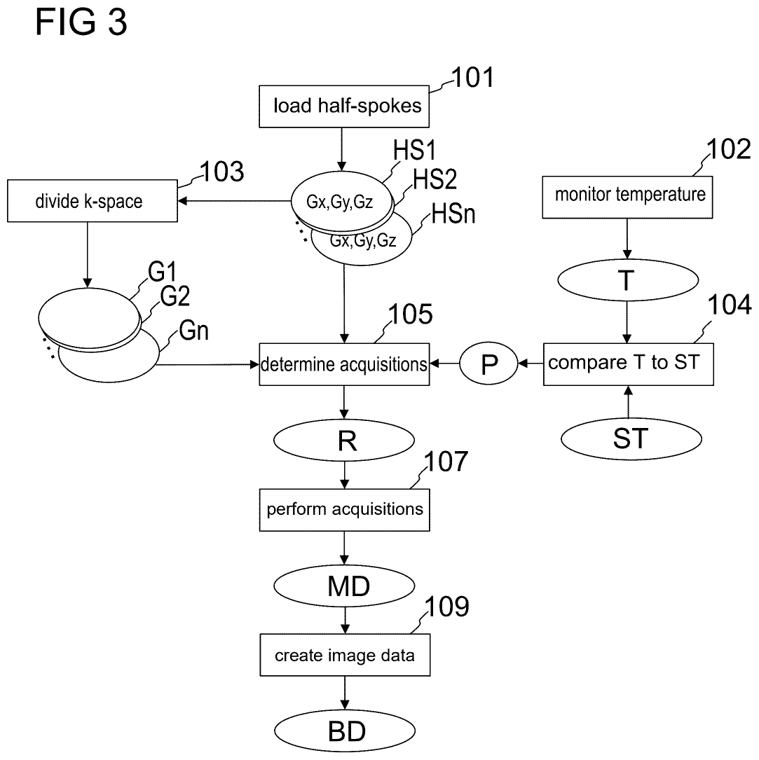

Further advantages are shown in FIG. 3, which is a schematic flow diagram of a method according to the disclosure for the acquisition of scan data MD of an examination object U by means of a magnetic resonance system 1 with a sequence using ultra-short echo times.

Herein, the half-spokes HS1, HS2, . . . , HSn to be sampled in k-space for the desired acquisitions A are loaded with the associated gradients Gₓ, G_{y}, Gₓ to be switched for spatial encoding on three axes x, y, z of a gradient unit 5 of the magnetic resonance system (block 101).

A sequence R of acquisitions A of scan data MD to be acquired one after the other along each half-spoke HS1, HS2, . . . , HSn with a distribution of the gradients Gₓ, G_{y}, Gₓ to be switched on the axes x, y, z that is optimized with respect to the load on the axes x, y, z is determined (block 105). The optimized distribution can in particular achieve the most uniform possible distribution of loads on the axes x, y, z caused by the gradients Gₓ, G_{y}, Gₓ to be switched on the axes x, y, z.

The determination of the sequence R can comprise randomly selecting half-spokes HS1, HS2, . . . , HSn of the half-spokes HS1, HS2, . . . , HSn to be sampled, which are acquired one after the other. Up to now, the half-spokes HS1, HS2, . . . , HSn to be sampled have been sampled according to a sorted sequence one after the other, wherein, for example, for acquisitions A of scan data MD in all three dimensions of k-space, different angles are actuated one after the other in ascending order in two spatial directions of k-space and, in the third spatial direction of k-space, the gradients to be switched for the half-spokes to be sampled are sorted one after the other from a maximum gradient strength in negative orientation in the third spatial direction, increasing in increments to the maximum gradient strength in positive orientation in the third spatial direction. For an axis of a gradient unit with which gradients are generated in such a third spatial direction, this means that high values for the gradient strengths of the gradients to be switched must in each case be achieved and maintained both at the beginning and at the end of such a sorted sequence over a longer period of time during which a plurality of acquisitions of scan data are performed. This places an enormous load on the affected axis of the gradient unit.

The above-proposed random selection of a sequence R of acquisitions A of scan data MD to be acquired one after the other along each half-spoke HS1, HS2, . . . , HSn can better distribute the load of the gradient unit 5 over the different axes x, y, z of the gradient unit 5.

The determination of the sequence R can also comprise inserting pauses P in which no gradients are switched on at least one axis x, y, z of the gradient unit 5, at least for a cooling period encompassed by the pause P. Inserting such pauses P can ensure that the gradient unit 5 is not overloaded.

Additionally or alternatively, it is possible that the determination of the sequence R takes place under the condition that a gradient strength of a gradient to be switched on at least one, in particular each, of the axes x, y, z during a first acquisition of scan data of a half-spoke is not a next larger or next smaller gradient strength of all the gradient strengths of the gradient strengths to be switched than a gradient strength of a gradient to be switched on the same axis in a subsequent acquisition of scan data following the first acquisition of scan data of a half-spoke of the half-spokes to be sampled.

In this way, it is possible to achieve a better distribution of a load on a gradient unit 5 during the acquisitions A of scan data MD along the half-spokes HS1, HS2, . . . , HSn to be sampled on the axes x, y, z of the gradient unit 5. Herein, for example, if a half-spoke randomly selected as the next half-spoke does not satisfy the condition, another random selection can be made. This can be repeated until the condition is satisfied or an abort criterion is reached. If necessary, a pause P can also be inserted in such a way that the consecutive half-spokes HS1, HS2, . . . , HSn to be sampled in the sequence R that violate the condition are separated from one another in time by the pause P.

The determination of the sequence R can comprise dividing the k-space into at least two, for example four or eight, in particular 16, segments (block 103), which are in each case contiguous segments of the sphere spanned by the half-spokes to be sampled in k-space. The half-spokes HS1, HS2, . . . , HSn to be sampled can then be divided into groups G1, G2, . . . , Gn according to the segment in which they lie. The half-spokes to be sampled in a group G1, G2, . . . , Gn can then be acquired one after the other within the determined sequence R. In this way, it can be prevented that gradient strengths of gradients to be switched in consecutive acquisitions A of scan data MD of the half-spokes HS1, HS2, . . . , HSn to be sampled are subject to large fluctuations and/or frequent inversions in their orientation. Such a division into segments can therefore prevent that, over a plurality of repetitions of acquisitions A of scan data MD in each case along one of the half-spokes HS1, HDd2, . . . , HSn to be sampled, an axis of a gradient unit and also a polarity corresponding to the orientation of the gradient to be switched occurs too frequently in consecutive acquisitions A of scan data MD of half-spokes HS1, HS2, . . . , HSn to be sampled.

The determination of the sequence R within a group G1, G2, . . . , Gn can comprise randomly selecting half-spokes HS1, HS2, . . . , HSn of the half-spokes HS1, HS2, . . . , HSn to be sampled from the group G1, G2, . . . , Gn which are acquired one after the other. By randomly selecting a sequence R of acquisitions A of scan data MD to be acquired one after another within a group G1, G2, . . . , Gn along each half-spoke HS1, HS2, . . . , HSn, the load on the gradient unit 5 can be better distributed over the different axes x, y, z of the gradient unit 5 assigned to the segment of the group G1, G2, . . . , Gn.

The determination of the sequence R within a group can take place under the condition that a gradient strength of a gradient to be switched on at least one, in particular each, of the axes x, y, z during a first acquisition of scan data of a half-spoke of the group of gradients to be switched is not a next larger or next smaller gradient strength of all the gradient strengths of the gradient strengths to be switched in the group than a gradient strength of a gradient to be switched on the same axis in a subsequent acquisition of scan data following the first acquisition of scan data of a half-spoke to be sampled of the group of the gradients to be switched.

In this way, it is possible to achieve a better distribution of the load on the gradient unit 5 during the acquisitions A of scan data MD along the half-spokes of a group to be sampled over the axes of x, y, z of the gradient unit 5 assigned to the segment of the group. Herein, for example, if a half-spoke of the group randomly selected as the next half-spoke does not satisfy the condition, another random selection can be made. This can be repeated until the condition is satisfied or an abort criterion is reached. If necessary, a pause P can also be inserted in such a way that the consecutive half-spokes of the group to be sampled in the sequence R are separated from one another in time by the pause P.

Gradients switched before a pause P inserted between two acquisitions A of scan data MD along half-spokes HS1, HS2, . . . , HSn to be sampled can be ramped down during the pause P and/or gradients to be switched after the pause P for an acquisition A of scan data of half-spokes HS1, HS2, . . . , HSn to be sampled following the pause can be ramped up during the pause P after the cooling period until they have reached a gradient strength required for the subsequent acquisition A of scan data MD. In this way, the duration of a change can be used to control a gradient strength of voltages applied to the gradient unit 5.

As illustrated above with reference to FIG. 1 using the example of a PETRA sequence, before each acquisition A of scan data MD of a half-spoke HS1, HS2, . . . , HSn, at least one RF pulse RF1 is radiated into the examination object U. At least one such RF pulse RF1 can also be radiated during a pause P so that a rhythm of radiated RF pulses RF1 is not interrupted by the pause P and a steady state in the magnetization of the spins in the examination object is maintained. If a pause P of a longer duration than a repetition time TR is to be inserted, a plurality of RF pulses RF1 can also be radiated during the pause P.

The temperature T of the gradient unit 5 can be monitored (block 102). The monitoring can use one or more conventional techniques. If monitoring the temperature T of the gradient unit 5 reveals that the temperature T of the gradient unit 5 reaches an upper threshold value ST (block 104), a pause P can likewise be inserted to allow the gradient unit 5 to cool down.

Monitoring the temperature T of the gradient unit 5 in this way makes it possible to ensure that there is no overheating of the gradient unit 5.

The acquisitions A of scan data MD along the half-spokes HS1, HS2, . . . , HSn to be sampled are performed according to the determined sequence R (block 107).

Based on the acquired scan data MD, image data BD can be created, for example using a Fourier transform (block 109).

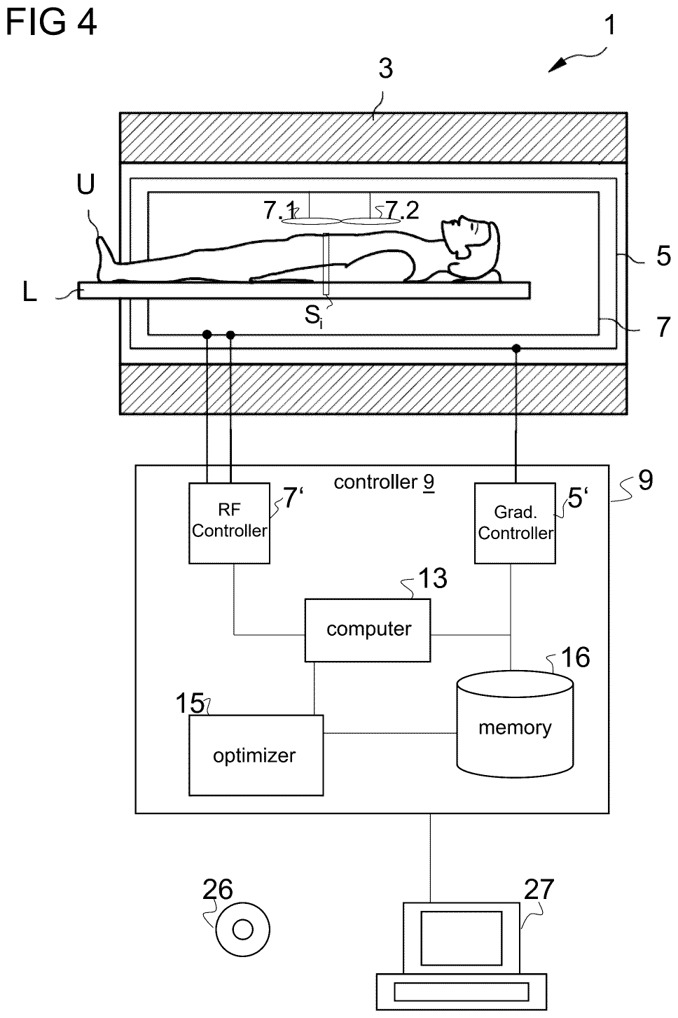

FIG. 4 schematically depicts a magnetic resonance system 1 according to the disclosure. The system 1 may include a magnet unit 3 configured to generate the main magnetic field, a gradient unit 5 configured to generate the gradient fields, a radio-frequency (RF) unit 7 configured to radiate (transmit) and/or receive radio-frequency signals, and a controller (control facility) 9 configured to perform a method according to the disclosure. The magnet unit 3, gradient unit 5, and RF unit may collectively be referred to as a scanner. The depiction of the controller 9 in FIG. 2 is purely by way of example. A controller 9, according to the disclosure and configured to perform a method according to the disclosure, may alternatively (or additionally) be embodied independently of a magnetic resonance system 1 without restriction.

In FIG. 4, these subunits of the magnetic resonance system 1 are only roughly schematically depicted. The radio-frequency unit 7 can consist of a plurality of subunits and, for example, comprise a plurality of coils. The radio-frequency unit 7 can comprise a body coil that is permanently integrated in the magnetic resonance system 1 and can comprise two or more antenna elements. Furthermore, the radio-frequency unit 7 can comprise one or more different local coils 7.1 and 7.2 which may be configured to transmit radio-frequency signals, receive the triggered radio-frequency signals, or both, and can in turn comprise a plurality of antenna elements and associated coil channels.

To examine an examination object U, for example, a patient or a phantom, said examination object can be placed on a bed L in the magnetic resonance system 1 within the scan volume thereof. The layer Si represents an exemplary target volume of the examination object in which a field of view can be selected and from which echo signals can be acquired and captured as scan data.

The controller 9 is used to control the magnetic resonance system 1 and may control the gradient unit 5 by a gradient controller 5′, and the radio-frequency unit 7 by a radio-frequency transceiver controller 7′. The radio-frequency unit 7 may comprise a plurality of channels on which signals can be transmitted or received. The controller 9 may include processing circuitry configured to perform one or more functions and/or operations of the controller 9. Additionally, or alternatively, one or more components (e.g., gradient controller 5′, RF transceiver controller 7′, computer 13, optimizer 15, memory 16) of the controller 9 may include processing circuitry that is configured to perform one or more respective functions of the component(s).

Together with its radio-frequency transmit-receive controller 7′, the radio-frequency unit 7 may be configured to generate and radiate (transmit) an alternating radio-frequency field for manipulating spins in a region to be manipulated of the examination object U (for example in slices S to be scanned). Herein, the center frequency of the alternating radio-frequency field, also referred to as the B1 field, is generally set as close as possible to the resonant frequency of the spins to be manipulated. Deviations of the center frequency from the resonant frequency are referred to as off-resonance. To generate the B1 field, controlled currents are applied to the RF coils in the radio-frequency unit 7 by means of the radio-frequency transmit-receive controller 7′.

Furthermore, the controller 9 may comprise an optimization unit (optimizer) 15 configured to for the optimized determination according to the disclosure of a sequence of half-spokes to be sampled consecutively. Overall, the controller 9 may be configured to the magnetic resonance system 1, which may include performing a method according to the disclosure.

A computing unit (computer, processor, processing circuitry) 13, comprised by the controller 9, may be configured to execute computing operation(s) required for the necessary scans and determinations. Intermediate results and results required or ascertained for this purpose can be stored in a memory unit 16 of the controller 9. Herein, the units depicted should not necessarily be understood to be physically separate units, but only represent a subdivision into meaningful units, which, for example, can also be realized in fewer units, or even in only one physical unit.

An input/output facility (input/output interface, computer) 27 of the magnetic resonance system 1 can, for example, be used by a user to forward control instructions to the magnetic resonance system and/or to display results of the controller 9 such as, for example, image data.

A method described herein can also be present in the form of a computer program comprising instructions that cause the controller 9 to execute the described method. Likewise, there may be a computer-readable storage medium 26 comprising instructions which, when executed by a controller 9 of a magnetic resonance system 1, cause the controller to execute the described method.

To enable those skilled in the art to better understand the solution of the present disclosure, the technical solution in the embodiments of the present disclosure is described clearly and completely below in conjunction with the drawings in the embodiments of the present disclosure. Obviously, the embodiments described are only some, not all, of the embodiments of the present disclosure. All other embodiments obtained by those skilled in the art on the basis of the embodiments in the present disclosure without any creative effort should fall within the scope of protection of the present disclosure.

It should be noted that the terms “first”, “second”, etc. in the description, claims and abovementioned drawings of the present disclosure are used to distinguish between similar objects but not necessarily used to describe a specific order or sequence. It should be understood that data used in this way can be interchanged as appropriate so that the embodiments of the present disclosure described here can be implemented in an order other than those shown or described here. In addition, the terms “comprise” and “have” and any variants thereof are intended to cover non-exclusive inclusion. For example, a process, method, system, product or equipment comprising a series of steps or modules or units is not necessarily limited to those steps or modules or units which are clearly listed, but may comprise other steps or modules or units which are not clearly listed or are intrinsic to such processes, methods, products or equipment.

References in the specification to “one embodiment,” “an embodiment,” “an exemplary embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The exemplary embodiments described herein are provided for illustrative purposes, and are not limiting. Other exemplary embodiments are possible, and modifications may be made to the exemplary embodiments. Therefore, the specification is not meant to limit the disclosure. Rather, the scope of the disclosure is defined only in accordance with the following claims and their equivalents.

Embodiments may be implemented in hardware (e.g., circuits), firmware, software, or any combination thereof. Embodiments may also be implemented as instructions stored on a machine-readable medium, which may be read and executed by one or more processors. A machine-readable medium may include any mechanism for storing or transmitting information in a form readable by a machine (e.g., a computer). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general-purpose computer.

The various components described herein may be referred to as “modules,” “units,” or “devices.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such modules, units, or devices, as applicable and relevant, may alternatively be referred to herein as “circuitry,” “controllers,” “processors,” or “processing circuitry,” or alternatively as noted herein.

For the purposes of this discussion, the term “processing circuitry” shall be understood to be circuit(s) or processor(s), or a combination thereof. A circuit includes an analog circuit, a digital circuit, data processing circuit, other structural electronic hardware, or a combination thereof. A processor includes a microprocessor, a digital signal processor (DSP), central processor (CPU), application-specific instruction set processor (ASIP), graphics and/or image processor, multi-core processor, or other hardware processor. The processor may be “hard-coded” with instructions to perform corresponding function(s) according to aspects described herein. Alternatively, the processor may access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary embodiments described herein, the memory is any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM), The memory can be non-removable, removable, or a combination of both.

1. A method for acquisition of scan data of an examination object by a magnetic resonance system with a sequence using ultra-short echo times comprising:
loading half-spokes to be sampled in k-space for the desired acquisitions in k-space with associated gradients to be switched on three axes of a gradient unit of the magnetic resonance system for spatial encoding;
determining a sequence of acquisitions of scan data to be acquired one after the other along each of the half-spokes with a distribution of the gradients to be switched on an axis that is optimized with respect to the load on the axis; and
performing the acquisitions of the scan data along the half-spokes to be sampled according to the determined sequence.

2. The method as claimed in claim 1, wherein the determination of the sequence comprises randomly selecting half-spokes of the loaded half-spokes to be sampled, which are acquired one after the other.

3. The method as claimed in claim 1, wherein the determination of the sequence is based on a gradient strength of a gradient to be switched on at least one of the axes during a first acquisition of scan data of a half-spoke is not a next larger or next smaller gradient strength of all gradient strengths to be switched than a gradient strength of a gradient to be switched on a same axis in a subsequent acquisition of scan data following the first acquisition of scan data of a half-spoke of the half-spokes to be sampled.

4. The method as claimed in claim 1, wherein the determination of the sequence comprises:
dividing the k-space into at least two segments; and
dividing the half-spokes to be sampled into groups according to a segment in which they lie, wherein the half-spokes to be sampled of a group are acquired one after the other in the determined sequence.

5. The method as claimed in claim 4, wherein the determination of the sequence within a group comprises randomly selecting half-spokes of the half-spokes to be sampled of the group, which are acquired one after the other.

6. The method as claimed in claim 4, wherein the determination of the sequence within a group is based on a gradient strength of a gradient to be switched on at least one of the axes during a first acquisition of scan data of a half-spoke of the group is not a next larger or next smaller gradient strength to be switched of all the gradient strengths to be switched in the group than a gradient strength of a gradient to be switched on the same axis in a subsequent acquisition of scan data following the first acquisition of scan data of a half-spoke of the half-spokes to be sampled of the group of gradients to be switched.

7. The method as claimed in claim 1, wherein the determination of the sequence comprises inserting pauses in which no gradients are switched on at least one axis, at least for a cooling period encompassed by the pause.

8. The method as claimed in claim 7, wherein gradients switched before a pause are ramped down during the pause and/or gradients to be switched after the pause for an acquisition of scan data following the pause are ramped up during the pause after the cooling period until the gradients switched before the pause or the gradients to be switched after the pause have reached a gradient strength required for the subsequent acquisition of scan data.

9. The method as claimed in claim 7, wherein, before each acquisition of scan data of a half-spoke, at least one radio-frequency (RF) pulse is radiated into the examination object, and wherein at least one such RF pulse is also radiated during a pause, such that a rhythm of radiated RF pulses is not interrupted by the pause.

10. The method as claimed in claim 7, further comprising monitoring a temperature of the gradient unit; and inserting a pause based on the temperature reaching an upper threshold value.

11. One or more non-transitory media storing instructions that, when executed by one or more processors, cause the one or more processors to perform the method of claim 1.

12. An apparatus comprising:
one or more processors; and
memory storing instructions that, when executed by the one or more processors, cause the apparatus to perform the method of claim 1.

13. A magnetic resonance (MR) system comprising:
scanner; and
a controller configured to:
load half-spokes to be sampled in k-space for the desired acquisitions in k-space with associated gradients to be switched on three axes of the scanner for spatial encoding;
determine a sequence of acquisitions of scan data to be acquired one after the other along each of the half-spokes with a distribution of the gradients to be switched on an axis that is optimized with respect to the load on the axis; and
control the scanner to perform the acquisitions of the scan data along the half-spokes to be sampled according to the determined sequence.

14. The MR system of claim 13, wherein the scanner comprises a magnet unit, a gradient unit, and a radio-frequency unit; and the controller comprises a radio-frequency transmit-receive controller and an optimization unit.
